(19) United States
(12) Patent Application Publication
(10) Pub. No.: US 2006/0231135 A1
(43) Pub. Date: Oct. 19, 2006

(54) Raw material kit for electrolytic composition, electrolytic composition, and photosensitized solar cell

(76) Inventors: Shinji Murai, Sagamihara-shi (JP); Satoshi Mikoshiba, Yamato-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/389,213

(22) Filed: Mar. 27, 2006

(30) Foreign Application Priority Data
Mar. 31, 2005 (JP) 2005-100311

(51) Int. Cl. H01L 31/00

(52) U.S. Cl. 136/252; 429/199

(57) ABSTRACT

An electrolytic composition includes a mixture containing an electrolyte, an amine compound and an organic halide. The electrolyte contains iodine. The amine compound has a chain alkyl group. The organic halide has two or more halogen atoms per molecule.

### CROSS-REFERENCE TO RELATED APPLICATIONS

This application is based upon and claims the benefit of priority from prior Japanese Patent Application No. 2005-100311, filed Mar. 31, 2005, the entire contents of which are incorporated herein by reference.

### BACKGROUND OF THE INVENTION

1. Field of the Invention

The present invention relates to a raw material kit used for obtaining an electrolytic composition, an electrolytic composition obtained from this raw material kit for an electrolytic composition, and a photosensitized solar cell using this electrolytic composition.

2. Description of the Related Art

A general structure of a photosensitized solar cell is disclosed in Jpn. Pat. Appln. KOKAI Publication No. 01-220380. This solar cell includes an electrode (oxide electrode) constituted of a transparent semiconductor layer made of fine particles of metal oxide and having a dye carried on a surface thereof, a transparent electrode that opposes this electrode, and a liquid carrier-transport layer that is interposed between these electrodes. Such a solar cell is called a wet-type photosensitized solar cell because the carrier-transport layer is in a liquid form.

The photosensitized solar cell operates through the following steps. Namely, light that is incident through the transparent electrode reaches the dye that is carried on the transparent semiconductor layer surface to excite the dye. The excited dye quickly passes electrons to the transparent semiconductor layer. On the other hand, the dye that is positively charged by losing the electrons receives electrons from the ions that have diffused from the carrier-transport layer to be electrically neutralized. The ions that have passed the electrons are diffused to the transparent electrode to receive electrons. The wet-type photosensitized solar cell operates by allowing this oxide electrode and the transparent electrode opposing thereto to serve as a negative electrode and a positive electrode, respectively.

In a wet-type photosensitized solar cell, a low-molecular-weight solvent is used. In order to prevent the leakage of this solvent, a shielding work must be carried out strictly. However, it is difficult to maintain the shielding for a long period. Evaporation of solvent and disappearance of the solvent by leakage raise a fear of deterioration of the element function and a fear of adverse effects on the environment. For these reasons, it is proposed to use ion-conductive solid electrolytes or electron-conductive solid organic substances instead of the liquid carrier-transport layer. Such a solar cell is called a solid photosensitized solar cell.

In these solid photosensitized solar cells, there is no fear of liquid leakage. However, there is a problem of low energy conversion efficiency.

Due to these reasons, a photosensitized solar cell having a gel electrolyte is proposed, as disclosed in Jpn. Pat. Appln. KOKAI Publication No. 2003-203520. Jpn. Pat. Appln. KOKAI Publication No. 2003-203520 discloses gelation of an electrolyte containing iodine by reaction of an acidic compound made of sulfonic acid and/or carboxylic acid with a basic compound selected from aliphatic amines, alicyclic amines, aromatic amines, and nitrogen-containing heterocyclic compounds.

However, in this photosensitized solar cell having a gel electrolyte, a further improvement of the energy conversion efficiency and a countermeasure against poor insulation at the time of scale reduction are demanded.

### BRIEF SUMMARY OF THE INVENTION

According to one aspect of the invention, there is provided a photosensitized solar cell comprising:

an n-type semiconductor electrode containing a dye;

a counter electrode which opposes the n-type semiconductor electrode; and

a gel electrolyte which is provided between the n-type semiconductor electrode and the counter electrode, the gel electrolyte containing a compound and an electrolyte containing iodine, and the compound being produced by reaction of an amine compound having a chain alkyl group with an organic halide having two or more halogen atoms per molecule.

According to another aspect of the invention, there is provided a electrolytic composition which is a mixture comprising:

an electrolyte containing iodine;

an amine compound having a chain alkyl group; and

an organic halide having two or more halogen atoms per molecule.

According to another aspect of the invention, there is provided a raw material kit for an electrolytic composition comprises:

a first material containing an amine compound having a chain alkyl group;

a second material containing an organic halide having two or more halogen atoms per molecule; and

a third material containing an electrolyte containing iodine.

According to another aspect of the invention, there is provided a raw material kit for an electrolytic composition comprises:

a first material which is a mixture containing an amine compound having a chain alkyl group, and a first electrolyte containing iodine; and

a second material which is a mixture containing an organic halide having two or more halogen atoms per molecule, and a second electrolyte containing iodine.

### BRIEF DESCRIPTION OF THE SEVERAL VIEWS OF THE DRAWING

FIGS. 1A to 1D are model views illustrating the steps of producing a dye-sensitized solar cell according to an embodiment of the present invention; and

FIG. 2 is a cross-sectional view illustrating a dye-sensitized solar cell according to an embodiment of the present invention.

### DETAILED DESCRIPTION OF THE INVENTION

A raw material kit for an electrolytic composition, an electrolytic composition, and a photosensitized solar cell according to embodiments of the present invention can improve the energy conversion efficiency and can retain the good insulation at the time of scale reduction.

First, the raw material kit for an electrolytic composition and an electrolytic composition will be described.

This raw material kit for an electrolytic composition contains raw materials that become an electrolytic composition by being mixed.

The raw materials may be in a non-mixed state in which they are not mixed with each other. A first raw material kit for an electrolytic composition comprises:

a first material containing an amine compound having a chain alkyl group;

a second material containing an organic halide having two or more halogen atoms per molecule; and

a third material containing an electrolyte containing iodine.

Also, the raw materials may be in a state in which a part of the raw materials is mixed. A second raw material kit for an electrolytic composition comprises:

a first material which is a mixture containing an amine compound having a chain alkyl group, and a first electrolyte containing iodine; and

a second material which is a mixture containing an organic halide having two or more halogen atoms per molecule, and a second electrolyte containing iodine. When a mixture is contained in the raw material kit, the second raw material kit may be used having, for example, the first material being a mixture A in which the amine compound is dissolved or dispersed in a part of the electrolyte as the first electrolyte and the second material being a mixture B in which the organic halide is dissolved or dispersed in the rest of the electrolyte as the second electrolyte.

The electrolytic composition is a mixture of an electrolyte containing iodine, an amine compound having a chain alkyl group, and an organic halide having two or more halogen atoms per molecule.

The electrolytic composition can be obtained by mixing the raw materials of the first raw material kit, or by mixing the raw materials of the second raw material kit. As a mixing method, the methods described in the following (a) to (b) can be raised, for example.

(a) A first raw material kit in which an electrolyte as a third raw material, an amine compound as a first raw material, and an organic halide as a second raw material are not mixed with each other is prepared. Into the electrolyte, the amine compound and the organic halide are dissolved to prepare an electrolytic composition. Or the amine compound and the organic halide are dissolved and deposited into the electrolyte, followed by phase separation to prepare an electrolytic composition. Or the amine compound and the organic halide are dispersed into the electrolyte to prepare an electrolytic composition.

(b) The amine compound is dissolved into a part of the electrolyte (first electrolyte) to prepare a raw material composition A as the first raw material of the second raw material kit. Or the amine compound is dissolved and deposited into a part of the electrolyte, followed by phase separation to prepare a raw material composition A. Or the amine compound is dispersed into a part of the electrolyte to prepare a raw material composition A. Into the rest of the electrolyte as the second electrolyte, the organic halide is dissolved to prepare a raw material composition B as the second raw material of the second raw material kit. Or the organic halide is dissolved and deposited into the rest of the electrolyte, followed by phase to prepare a raw material composition B. Or the organic halide is dispersed into the rest of the electrolyte to prepare a raw material composition B. A second raw material kit containing the obtained raw material composition A as the first raw material and the raw material composition B as the second raw material is stored. The stored raw material composition A and raw material composition B are mixed when needed, so as to obtain an electrolytic composition.

By obtaining an electrolytic composition using the above-described raw material kit for electrolytic composition, the gelation reaction can be restrained when the electrolytic composition is injected as a gel electrolyte precursor into a solar cell. Because an amine compound having a long-chain alkyl group and an organic halide having two or more halogen atoms per molecule have low reactivity with each other in a room temperature atmosphere. Therefore, the rise in the viscosity of the electrolytic composition during the injection can be restrained. For this reason, after the electrolytic composition is uniformly dispersed into the cell, the gelation reaction can be started by thermal treatment or the like, so as to form a gel electrolyte uniformly within the cell. This improves the energy conversion efficiency of the solar cell.

Also, since the obtained gel electrolyte is excellent in shape retaining property, the insulation can be ensured even when the thickness of the gel electrolyte layer is reduced due to reduction in the thickness of the solar cell, thereby lowering the ratio of occurrence of poor insulation.

Hereafter, the amine compound, the organic halide, and the electrolyte will be described.

(Amine Compound Having A Long-Chain Alkyl Group)

Examples of this amine compound include aliphatic amines whose skeleton is a long-chain alkyl group, alicyclic amines having a long-chain alkyl group as a side chain, aromatic amines having a long-chain alkyl group as a side chain, nitrogen-containing heterocyclic compounds having a long-chain alkyl group as a side chain, and others.

As the long-chain alkyl group, a substituted or non-substituted hydrocarbon group having 8 to 30 carbon atoms is preferable. The number of carbon atoms should preferably be in a range of 8 to 20. When the number of carbon atoms is 20 or less, the state of phase separation can be maintained more stably. Here, it is sufficient that at least one long-chain alkyl group is contained in a molecule, and two or more long-chain alkyl groups may be contained. As the hydrocarbon group, a substituent of octane, nonane, decane, undecane, dodecane, tridecane, tetradecane, pentadecane, hexadecane, heptadecane, octadecane, nonadecane, icosane, henicosane, docosane, tricosane, tetracosane, pentacosane, hexacosane, heptacosane, octacosane, nonacosane, triacosane, or the like, or a compound having a steroid skeleton such as cholesterol can be used, for example. The long-chain hydrocarbon group may have a branched chain.

As aliphatic amines, alicyclic amines, and aromatic amines, any of primary, secondary, and tertiary amines can be used. One kind or two or more kinds selected from aliphatic amines, alicyclic amines, aromatic amines and nitrogen-containing heterocyclic compounds can be used.

The nitrogen-containing heterocyclic ring of the nitrogen-containing heterocyclic compound may be an unsaturated ring or a saturated ring, and may have atoms other than nitrogen atoms. Examples of the unsaturated heterocyclic rings include pyrrolyl, imidazolyl, pyrazolyl, isothiazolyl, isoxazolyl, pyridyl, pyrazinyl, pyrimidinyl, pyridazinyl, indolizinyl, isoindolyl, indolyl, isoazoyl, purinyl, quinolizinyl, isoquinolyl, quinolyl, phthalazinyl, naphthyridinyl, quinoxalzinyl, quinazolinyl, cinnolinyl, pheridinyl, carbazole, carbolinyl, phenanthrolinyl, acridinyl, perimidinyl, phenanthrlolinyl, phenazinyl, phenothiazinyl, furazanyl, phenoxazinyl, pyrrolidinyl, pyrrolinyl, imidazolidinyl, imidazolinyl, pyrazolidinyl, pyrazolinyl, piperidyl, piperazinyl, indolinyl, isoindolinyl, quinuclidinyl, morpholinyl, 1-methyl imidazoyl, 1-ethyl imidazoyl, 1-propyl imidazoyl, pyridine, imidazole, thiazole, oxazole, and triazole group, and the like. Examples of the saturated heterocyclic rings include morpholine rings, piperidine rings, piperazine rings, and the like. Preferable nitrogen-containing heterocyclic rings are unsaturated heterocyclic rings, more preferably pyridine rings or imidazole rings. These may be substituted with an alkyl group or the like such as a methyl group.

Specific preferable examples of the amine compounds having a long-chain alkyl group will be exemplified as follows; however, the present invention is not limited to these alone. They include N,N,N′,N′-tetramethyl-1,8-diaminooctane, N,N,N′,N′-tetramethyl-1,12-diaminododecane, 1,12-diaminododecane, 1,16-hexadecyldiimidazole, 1,18-octadecyldiimidazole, N,N-dimethylaminooctadecane, 1-octadecylimidazole, 1-octadecyl-2-heptadecylimidazole, 2-octadecylimidazole, bis(N,N,N′,N′-tetradecylamino)cyclohexane, 4,4′-(N,N,N′,N′-tetradodecylamino)dicyclohexylmethane, bis(N,N,N′,N′-tetradodecylamino)-m-xylene, 3,3′-dioctadecyloxy-2,2′-bipyridyl, 6,6″-dihexadecyloxy-2,2′:6′,2″-terpyridine, 1,12-dodecyl-bis(2-heptadecylimidazole and the like.

These amine compounds having a long-chain alkyl group have a property of being able to occur a reversible dissolution reaction and a reversible deposition reaction by being heated and cooled. In the present invention, the heating means a temperature of room temperature or higher, specifically a temperature range from 40° C. to 150° C., and the cooling means a temperature of 150° C. or lower, specifically a temperature of 80° C. or lower, preferably 60° C. or lower. The deposition means that these amine compounds assume a form of colloid, micelle, crystal, or the like in the electrolyte, and may be a state in which the nitrogen atoms constituting the reaction site of the amine compound are separated from the organic halide.

Further, as long as the cross-linking reaction can be restrained by deposition of these amine compounds, they may have any size; however, the amine compounds preferably have an average particle size within a range of 100 μm or less, more preferably 30 μm or less, still more preferably 10 μm or less, in order to improve the diffusion property of the electrolyte when the electrolyte is injected by capillary phenomenon into the solar cell. Here, the dissolution may mean a state in which at least a part of the amine compound is dissolved in the electrolyte. Furthermore, it is still more preferable if the heat absorption peak deriving from the dissolution of the amine compound in the electrolyte is confirmed by differential scanning colorimetry (DSC) or the like.

Also, amine compounds contained into microcapsules have a low compatibility with electrolytes and cause phase separation from the electrolyte, so that the gelation of the electrolytic composition at room temperature can be further restrained. By restraining the gelation at room temperature, the occurrence of the gelation during the impregnation with the electrolytic composition can be avoided when the reaction area of the electrode is increased. Therefore, the gelation can be promoted by a heating treatment of 50° C. to 200° C. after the electrode is impregnated with the electrolytic composition, so that the distribution of the gel electrolyte can be made uniform even if the reaction area of the electrode is increased.

As the amine compounds contained into microcapsules, those are known in which an amine compound is dispersed into an epoxy resin, and an isocyanate compound is added thereto to create microcapsules of urethane on the surface of the amine compound, and are commercially available under the trade name of Novacure from Asahi Kasei Corporation.

The nitrogen-containing heterocyclic compounds can reduce the reverse electron reaction by being bonded to hydroxyl groups that are bonded to the surface of the n-type semiconductor electrode (for example, those using TiO₂ as an n-type semiconductor). For this reason, a high voltage can be obtained in a solar cell. Among these, nitrogen-containing heterocyclic compounds having a pyridine ring can further improve the gelation reaction restraining effect at room temperature and the shape retaining property, and are therefore preferable.

Specific preferable examples of the nitrogen-containing heterocyclic compounds include those having a long-chain alkyl group such as polyvinylpyridine, polyvinylimidazole, and the like.

The weight-average molecular weight of each of the aromatic amine polymers and polymers of the nitrogen-containing heterocyclic compounds is preferably set to be within a range from 500 to 1,000,000. This is due to the following reason. When the molecular weight is larger than 1,000,000, there is a fear that each of the polymers may not be dissolved into the electrolyte. On the other hand, when the molecular weight is set to be smaller than 500, there is a fear that the gelation will be difficult. A more preferable range is 1,000 to 300,000.

In the case of homopolymers in which monomers of one kind are polymerized, the polymer preferably has a long-chain alkyl group within a molecule. The long-chain alkyl group is preferably a substituted or non-substituted hydrocarbon group having 8 to 30 carbon atoms. Here, it is sufficient that at least one long-chain alkyl group is contained in a molecule, and two or more long-chain alkyl groups may be contained. As the hydrocarbon group, a substituent of octane, nonane, decane, undecane, dodecane, tridecane, tetradecane, pentadecane, hexadecane, heptadecane, octadecane, nonadecane, icosane, henicosane, docosane, tricosane, tetracosane, pentacosane, hexacosane, heptacosane, octacosane, nonacosane, triacosane, or the like, or a compound having a steroid skeleton such as cholesterol can be used, for example. The long-chain hydrocarbon group may have a branched chain. In the case of copolymers in which two or more kinds of monomers are polymerized, it is preferable that at least one kind of the monomer is polyethylene, polypropylene, or the like having a low compatibility with the electrolytic solution. The copolymers may be random copolymers or block copolymers.

An example of the homopolymer used as the amine compound is polyvinylpyridine, polyvinylimidazole. It is preferable that polyvinylpyridine should be of such a structure that a chain alkyl group having 8 to 30 carbon atoms is bonded as a substituent to its pyridine ring. Further, it is preferable that polyvinylimidazole should be of such a structure that a chain alkyl group having 8 to 30 carbon atoms is bonded as a substituent to its imidazole ring. The aforementioned hydrocarbon group can be used as the chain alkyl group having 8 to 30 carbon atoms.

(Organic Halide Having Two Or More Halogen Atoms Per Molecule)

In this organic halide, halogen atoms of different kinds may be present in one molecule to let the total number of the halogen atoms be two or more; however, two or more halogen atoms of one kind may be present in one molecule. When the number of halogen atoms per molecule is one, the polymerization degree of the polymer obtained from the amine compound and the organic halide will be low, raising a fear that the gelation of the electrolytic composition will be difficult. A more preferable range of the number of halogen atoms per molecule is 2 or more and 1,000,000 or less.

Examples of the organic halides include multifunctional halides such as dibromomethane, dibromoethane, dibromopropane, dibromobutane, dibromopentane, dibromohexane, dibromoheptane, dibromooctane, dibromononane, dibromodecane, dibromoundecane, dibromododecane, dibromotridecane, dichloromethane, dichloroethane, dichloropropane, dichlorobutane, dichloropentane, dichlorohexane, dichloroheptane, dichlorooctane, dichlorononane, dichlorodecane, dichloroundecane, dichlorododecane, dichlorotridecane, diiodomethane, diiodoethane, diiodopropane, diiodobutane, diiodopentane, diiodohexane, diiodoheptane, diiodooctane, diiodononane, diiododecane, diiodoundecane, diiodododecane, diiodotridecane, 1,2,4,5-tetrakisbromomethylbenzene, 1,4-bisbromomethylbenzene, 1,4-bisiodomethylbenzene, 10,10-bisbromomethylnonadecane, epichlorohydrin oligomer, epibromohydrin oligomer, hexabromocyclododecane, tris(3,3-dibromo-2-bromopropyl)isocyanuric acid, 1,2,3-tribromopropane, diiodoperfluoroethane, diiodoperfluoropropane, diiodoperfluorohexane, polyepichlorohydrin, copolymer of polyepichlorohydrin and polyethylene ether, polyepibromohydrin, and polyvinyl chloride. One kind or two or more kinds of organic halides can be used.

Among the organic halides, a bromomethylbenzene derivative such as 1,2,4,5-tetrakisbromomethylbenzene is preferable. Such a bromomethylbenzene derivative can enhance the effect of improving the shape retaining property of the gel electrolyte, and also can reduce the interfacial resistance between the gel electrolyte and the electrode.

(Electrolyte)

The electrolyte contains iodine (I₂).

Preferably, the electrolyte further contains a reversible redox couple made of I⁻ and I₃⁻. Such a reversible redox couple can be supplied, for example, from a mixture of iodine molecule (I₂) and iodide.

The redox couple preferably exhibits an redox potential that is smaller by 0.1 to 0.6V than the oxidation potential of the dye mentioned later. In a redox couple exhibiting an redox potential that is smaller by 0.1 to 0.6V than the oxidation potential of a dye, a reduction seed such as I⁻ can receive positive holes from the oxidized dye. An electrolyte containing this redox couple can increase the speed of electric charge transfer between the n-type semiconductor electrode and the electroconductive film, and can raise the open-circuit voltage.

The electrolyte preferably contains iodine (I₂) and an iodide. The iodide may be, for example, an iodide of an alkali metal, an iodide of an organic compound, a molten salt of an iodide, or the like.

As the molten salt of iodide, an iodide of a nitrogen-containing heterocyclic compound such as an imidazolium salt, a pyridinium salt, a quaternary ammonium salt, a pyrrolidinium salt, a pyrazolidinium salt, an isothiazolidinium salt, or an isooxazolidinium salt can be used.

Examples of the molten salts of iodide include 1-methyl-3-propylimidazolium iodide, 1,3-dimethylimidazolium iodide, 1-methyl-3-ethylimidazolium, iodide, 1-methyl-3-pentylimidazolium iodide, 1-methyl-3-isopentylimidazolium iodide, 1-methyl-3-hexylimidazolium iodide, 1,2-dimethyl-3-propylimidazolium iodide, 1-ethyl-3-isopropylimidazolium iodide, 1-propyl-3-propylimidazolium iodide, pyrrolidinium iodide, ethylpyridinium iodide, butylpyridinium iodide, hexylpyridinium iodide, trihexylmethylammonium iodide, and others. As the molten salt of iodide, one kind or two or more kinds selected from the above-described kinds can be used.

Iodides of nitrogen-containing heterocyclic compounds and aliphatic nitrogen compounds whose anion site is converted into a cyanide molten salt such as N(CN)₂, C(CN)₃, Si(CN)₃, B(CN)₄, Al(CN)₄, P(CN)₂, P(CN)₆, or As(CN)₆ have a low viscosity, and can be used as a mixture with an iodide molten salt. These cyanide molten salts can reduce the viscosity of the electrolyte, and can be easily penetrated into the n-type semiconductor electrode. Also, these cyanide molten salts can increase the ionic conductivity of the gel electrolyte.

(Organic Solvent)

The raw material kit for an electrolytic composition and the electrolytic composition can further contain an organic solvent. An electrolytic composition containing an organic solvent can reduce the viscosity and can easily penetrate into the n-type semiconductor electrode. Also, an electrolytic composition containing an organic solvent can increase the ionic conductivity of the gel electrolyte.

Particularly, it is preferable to use a solvent that can exhibit an excellent ionic conductivity because of having a high ionic mobility due to having a low viscosity or because of having a high effective carrier concentration due to having a high electric permittivity, or because of having both of these properties. For example, ester carbonates such as ethylene carbonate and propylene carbonate, lactones such as γ-butyrolactone, γ-valerolactone, and δ-valerolactone, ethers such as 1,2-dimethoxyethane, diethoxyethane, ethylene glycol dimethyl ether, polyethylene glycol dimethyl ether, and 1,4-dioxane, alcohols such as ethanol, ethylene glycol monomethyl ether, and polyethylene glycol monoalkyl ether, glycols such as ethylene glycol, propylene glycol, and polyethylene glycol, tetrahydrofurans such as tetrahydrofuran and 2-methyltetrahydrofuran, nitriles such as acetonitrile, glutarodinitrile, propionitrile, methoxyacetonitrile, and benzonitrile, carboxylic esters such as methyl acetate, ethyl acetate, and ethyl propionate, phosphate triesters such as trimethyl phosphate and triethyl phosphate, heterocyclic compounds such as N-methylpyrrolidone, 2-methyl-1,3-dioxolane, and sulfolane, nonprotonic organic solvents such as dimethyl sulfoxide, formamide, N,N-dimethylformamide, and nitromethane, and the like are preferable. Two or more kinds of these solvents may be mixed for use in accordance with the needs.

Assuming that the total raw material kit for an electrolytic composition and the total electrolytic composition are each 100 wt %, the content of the organic solvent is preferably 65 wt % or less. When the content of the organic solvent exceeds 65 wt %, there is a fear that a change in properties of the gel electrolyte occurs considerably, and also there is a possibility that the gelation will be inhibited. The content of the organic solvent is preferably 1 wt % or more and 20 wt % or less.

(Water)

The electrolytic composition can contain water as well. An electrolytic composition containing water can further enhance the energy conversion efficiency of a photosensitized solar cell.

Assuming that the sum amount of the molten salt of iodide and water is 100 wt %, the content of water in the electrolytic composition is preferably at most 10 wt %. Assuming that the sum amount of the molten salt of iodide and water is 100 wt %, a further preferable range of the content of water is 0.01 wt % or more and 10 wt % or less, and a most preferable range is 0.5 wt % or more and 5 wt % or less relative to the sum amount of 100 wt %.

Further, an electrolyte to which one or more kinds selected from the group consisting of electrically insulating particles, semiconductor particles, and electroconductive particles are added can be used. In the case of electrically insulating particles or semiconductor particles, they play a role as a spacer that electrically separates the semiconductor film and the counter electrode from each other. On the other hand, in the case of electroconductive particles, particles serially connected from the counter electrode gives electrons to the electrolyte. Therefore, in this case, the electrolyte layer (electric charge transfer layer) functions as an ion-electron conduction layer. However, when the semiconductor film and the counter electrode are short-circuited by the use of the electroconductive particles, the functional deterioration occurs, so that it is necessary to use the electroconductive particles while avoiding the short-circuiting. The size of these particles is preferably such that the diameter is 0.1 to 100 μm, more preferably 0.5 to 30 μm. The amount of addition of these particles to the electrolyte is preferably 2 to 80 mass %, more preferably 10 to 50 mass %.

As the electrically insulating particles, any substance inactive to the electrolyte is used. Such a substance may be, for example, oxide, amorphous oxide glass or crystalline oxide can be used. A specific preferable example of oxide glass is an oxide glass containing at least one kind of an element selected from aluminum, silicon, boron, and phosphorus. Also, a preferable example of crystalline oxide is aluminum oxide. Particles made of organic polymer can be used as the electrically insulating particles. As an organic polymer material that forms the particles, polymethyl methacrylate, polyethylene, polystyrene, polypropylene, polyvinylidene-di-fluorate, and the like can be raised as preferable examples.

As the semiconductor particles, single-element semiconductors such as silicon and germanium, group III-V compound semiconductors, metal chalcogenides (for example, oxides, sulfides, selenides, and the like), compounds having a perovskite structure (for example, strontium titanate, calcium titanate, sodium titanate, barium titanate, potassium niobate, and the like), and others can be raised as preferable examples.

As the electroconductive particles, any material that is inactive to the electrolyte and gives electrons quickly to the oxidizing agent in the electrolyte can be used. As a preferable material having such a property, Au, Pt, carbon (graphite, carbon black, acetylene black, cokes, carbon fiber, graphite carbon microbeads, and the like), Al, Pd, Ge, Ni, and others can be raised as examples. These may be used either as one kind alone or as a combination of plural kinds, and may be used by being combined such as allowing them to be carried. Also, particles with electron conductivity given by plating Au or Pt on the surface of substantially electrically insulating particles, or particles with improved electronic transfer rate by allowing Pt to be carried partially on the above-described carbon particles (particularly graphite), or the like are preferably used. Also, a foam metal can be used as well.

Next, a photosensitized solar cell will be described.

This photosensitized solar cell includes a substrate having a light-receiving surface, a transparent electroconductive film, an n-type semiconductor electrode, a counter electrode and a gel electrolyte. The transparent electroconductive film is formed on an inner surface of the substrate. The n-type semiconductor electrode is formed on the transparent electroconductive film and has a dye adsorbed on a surface thereof. The counter electrode has a counter substrate that faces the n-type semiconductor electrode. An electroconductive film is formed on a surface of the counter substrate which faces the n-type semiconductor electrode. The gel electrolyte is present between the electroconductive film of the counter electrode and the n-type semiconductor electrode.

Hereafter, the gel electrolyte, the transparent electroconductive film, the n-type semiconductor electrode, the dye, the counter substrate, and the electroconductive film will be described.

1) Gel Electrolyte

The gel electrolyte contains an electrolyte containing iodine and a gelating agent. The gelating agent is a compound produced by reaction of an amine compound having a long-chain alkyl group and an organic halide having two or more halogen atoms per molecule. As one example of the gel-producing reaction, in the case of reaction between 1,18-octadecyldiimidazole and 1,2,4,5-tetrakisbromomethylbenzene, in the state in which 1,18-octadecyldiimidazole is dispersed under phase separation in the electrolyte, the gelation does not proceed because the reaction is restrained. However, when 1,18-octadecyldiimidazole is dissolved in the electrolyte by being heated, it reacts with 1,2,4,5-tetrakisbromomethylbenzene for the first time to gelate the electrolyte.

This gel electrolyte is fabricated, for example, by preparing an electrolytic composition through the methods described in the above (a) to (b) and then gelating this electrolytic composition.

2) Transparent Electroconductive Film

The transparent electroconductive film preferably has low absorption in the visible light range and has an electric conductivity. Such a transparent electroconductive film is preferably a tin oxide film doped with fluorine, indium, or the like, a zinc oxide film doped with fluorine, indium, or the like, for example. Also, in view of preventing a rise in the resistance by improving the conductivity, a metal matrix having a low resistance is preferably wired in combination with the transparent electroconductive film.

3) N-Type Semiconductor Electrode

The n-type semiconductor electrode is preferably constructed with a transparent semiconductor having a low absorption in the visible light range. Such a semiconductor is preferably a metal oxide semiconductor. Specifically, oxide of a transition metal such as titanium, zirconium, hafnium, strontium, zinc, indium, yttrium, lanthanum, vanadium, niobium, tantalum, chromium, molybdenum, or tungsten, a perovskite such as SrTiO₃, CaTiO₃, BaTiO₃, MgTiO₃, or SrNb₂O₆, a mixture of these composite oxides or oxides, GaN, and the like can be raised as preferable examples.

As the dye that is adsorbed onto the surface of the n-type semiconductor electrode, ruthenium-tris type transition metal complexes, ruthenium-bis type transition metal complexes, osmium-tris type transition metal complexes, osmium-bis type transition metal complexes, ruthenium-cis-diaqua-bipyridyl complex, phthalocyanine, porphyrin, and the like can be raised as preferable examples.

4) Counter Substrate

This counter substrate preferably has low absorption in the visible light range and has an electric conductivity. Such a substrate is preferably a tin oxide film, a zinc oxide film, or the like.

5) Electroconductive Film

This electroconductive film can be formed, for example, from a metal such as platinum, gold, or silver.

This solar cell is manufactured, for example, by a method described below.

First, a cell unit is assembled that includes a substrate having a light-receiving surface, a transparent electroconductive film, an n-type semiconductor electrode and a counter electrode. The transparent electroconductive film is formed on an inner surface of the substrate. The n-type semiconductor electrode is formed on the transparent electroconductive film and has a dye adsorbed on a surface thereof. The counter electrode has a counter substrate that opposes the n-type semiconductor electrode. The electroconductive film is formed on a surface of the counter substrate opposing the n-type semiconductor electrode.

Next, an electrolytic composition prepared by the method described in the above (a) or (b) is injected into a gap that is present between the substrate and the counter substrate. Subsequently, the cell unit is sealed, followed by gelation of the electrolytic composition to obtain a photosensitized solar cell.

### EXAMPLES

Hereafter, Examples of the present invention will be described in detail with reference to the attached drawings.

### Example 1

After nitric acid was added to a high-purity titanium oxide (anatase) powder having an average primary particle size of 30 nm, the mixture was kneaded with pure water, followed by stabilization with a surfactant to fabricate a paste. This paste was printed on a dense part formed on a glass substrate by the screen printing method, followed by a thermal treatment at a temperature of 450° C. to form an n-type semiconductor electrode made of titanium oxide (anatase) particles and having a thickness of 2 μm. This screen printing and the thermal treatment were repeated for plural times, thereby eventually to form an n-type semiconductor electrode 4 containing anatase-phase titanium oxide particles 3 and having a thickness of 8 μm on a fluoride-doped tin oxide conductive film 2 as a transparent electroconductive film 2. This n-type semiconductor electrode 4 had a roughness factor of 1500. The roughness factor was determined from the nitrogen adsorption amount relative to the projected area of the substrate.

Subsequently, this was immersed for four hours into a 3×10⁻⁴M dried ethanol solution (temperature of about 80° C.) of cis-bis(thiocyanato)-N,N-bis(2,2′-dipyridyl-4,4′-dicarboxylic acid)-ruthenium (II) dihydrate, followed by drawing the resultant up in an argon gas stream to allow the ruthenium complex serving as a dye to be carried on the n-type semiconductor electrode 4 surface.

A fluorine-doped tin oxide electrode 6 (electroconductive film 6) having platinum attached thereto was formed on a glass substrate 7, thereby obtaining a counter electrode 5. By using spacers having a diameter of 30 μm, the counter electrode 5 was placed on the above-described substrate 1 on which the n-type semiconductor electrode 4 had been fabricated. The surroundings were fixed by fixation with an epoxy resin 8, leaving the electrolytic solution inlet open.

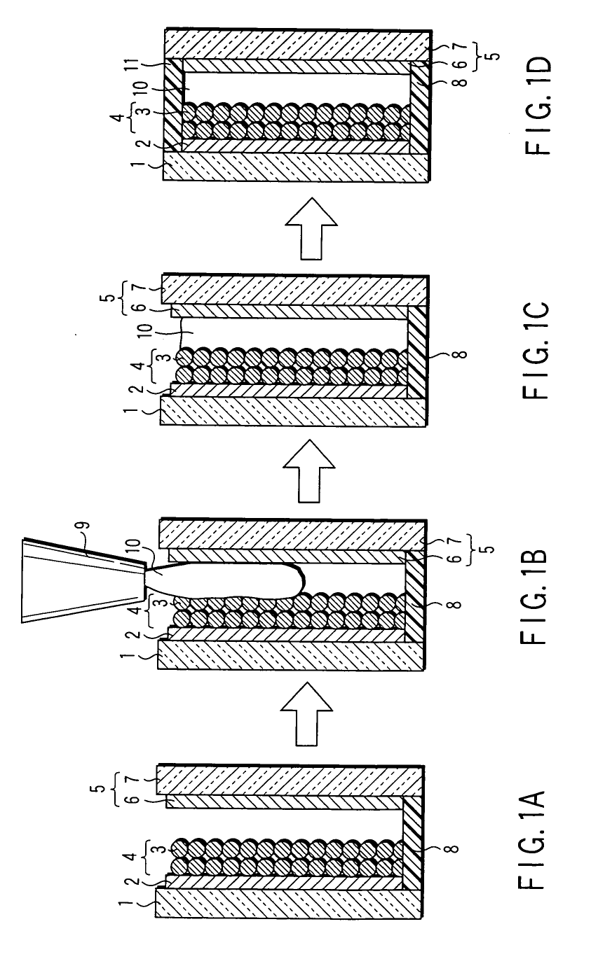

FIG. 1A shows a cross-sectional view of the obtained photoelectric conversion element unit.

Iodine 0.03M was dissolved in an 8:2 mixture liquid of 1-methyl-3-propylimidazolium iodide and 1-methyl-2-ethylimidazolium bisdicyanimide, so as to prepare an electrolyte. To 10 g of this electrolyte, 0.2 g of 1,18-octadecyldiimidazole and 0.22 g of 1,2,4,5-tetrakisbromomethylbenzene were added as a phase separation type catalyst to obtain an electrolytic composition.

Referring to FIGS. 1B and 1C, the electrolytic composition 10 was injected through the injection inlet 9 into the electrolytic solution inlet of the photoelectric conversion element unit so as to allow the electrolytic composition 10 to penetrate into the n-type semiconductor electrode 4 and to be injected between the n-type semiconductor electrode 4 and the tin oxide electrode 6 (electroconductive film 6).

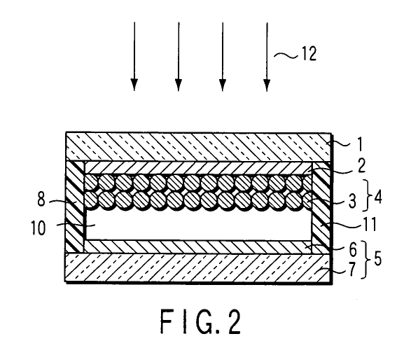

Subsequently, referring to FIG. 1D, the electrolytic solution inlet of the photoelectric conversion element unit was sealed with an epoxy resin 11, followed by heating on a hot plate of 60° C. for 30 minutes to produce a photoelectric conversion element, namely, a dye-sensitized solar cell having a thickness of 2 mm. FIG. 2 shows a cross-sectional view of the obtained solar cell.

In other words, the transparent electroconductive film 2 is formed on the glass substrate 1. The transparent n-type semiconductor electrode 4 is formed on the transparent electroconductive film 2. This semiconductor electrode 4 has an extremely large surface area because of being an assembly of fine particles 3. Also, a monomolecular layer of dye is formed on the surface of the semiconductor electrode 4. It is possible for the surface of the semiconductor electrode 4 to have a fractal shape having a self-similarity like a resin-like structure. The counter electrode 5 comprises the glass substrate 7 and the electroconductive film 6 formed on the surface of the glass substrate 7 that faces the semiconductor electrode 4. The gel electrolyte 10 is held in the pores of the semiconductor electrode 4 and is interposed between the semiconductor electrode 4 and the electroconductive film 6. In such a photosensitized solar cell, after the dye adsorbed on the surface of the n-type semiconductor electrode 4 absorbs the light 12 that is incident from the glass substrate 1, the dye passes electrons to the n-type semiconductor electrode 4, and the dye passes positive holes to the gel electrolyte 10, thereby to perform photoelectric conversion.

### Example 2

Dye-sensitized solar cells having a construction similar to the one described above in Example 1 were produced except that 1,16-hexadecyldiimidazole (blended amount of 0.28 g) was used instead of 1,18-octadecyldiimidazole.

### Example 3

Dye-sensitized solar cells having a construction similar to the one described above in Example 1 were produced except that 1,12-dodecyldiimidazole (blended amount of 0.2 g) was used instead of 1,18-octadecyldiimidazole.

### Example 4

Dye-sensitized solar cells having a construction similar to the one described above in Example 1 were produced except that 1,12-dodecyl-bis(2-heptadecylimidazole) with blended amount of 0.35 g was used instead of 1,18-octadecyldiimidazole.

### Example 5

Dye-sensitized solar cells having a construction similar to the one described above in Example 1 were produced except that polyvinylpyridine-co-ethylene (1:9, molecular weight of 10,000, blended amount of 0.2 g) was used instead of 1,18-octadecyldiimidazole.

### Example 6

Dye-sensitized solar cells having a construction similar to the one described above in Example 1 were produced except that polyvinylimidazole-co-ethylene (1:9, molecular weight of 10,000) was used instead of 1,18-octadecyldiimidazole.

### Example 7

Dye-sensitized solar cells having a construction similar to the one described above in Example 1 were produced except that 1,4-bisbromomethylbenzene (blended amount of 0.3 g) was used instead of 1,2,4,5-tetrakisbromomethylbenzene.

### Example 8

Dye-sensitized solar cells having a construction similar to the one described above in Example 1 were produced except that 1,4-bisiodomethylbenzene (blended amount of 0.35 g) was used instead of 1,2,4,5-tetrakisbromomethylbenzene.

### Example 9

A dye-sensitized solar cell having a construction similar to the one described above in Example 1 was produced except that 1-methyl-2-ethylimidazoliumtriscyanidemethide was used instead of 1-methyl-2-ethylimidazoliumbisdicyanimide.

### Example 10

A dye-sensitized solar cell having a construction similar to the one described above in Example 1 was produced except that polyvinylpyridine (blended amount of 0.2 g, molecular weight of 60,000) was used instead of 1,18-octadecyldiimidazole and that 1,18-dibromooctadecane (blended amount of 0.3 g) was used instead of 1,2,4,5-tetrakisbromomethylbenzene.

### Example 11

A dye-sensitized solar cell having a construction similar to the one described above in Example 1 was produced except that a microcapsule type amine compound (trade name: HX3088 manufactured by Asahi Kasei Corporation., blended amount of 0.29 g) was used instead of 1,18-octadecyldiimidazole.

### Example 12

A dye-sensitized solar cell was produced in a manner similar to the one described above in Example 1 except that the electrolyte described below was used.

A dye-sensitized solar cell having a construction similar to the one described above in Example 1 was produced except that 1-dodecylimidazole (0.03 g) was added instead of 1,18-octadecyldiimidazole and that lithium iodide (0.01 g) was added instead of 0.22 g of 1,2,4,5-tetrakisbromomethylbenzene.

### Example 13

A dye-sensitized solar cell was produced in a manner similar to the one described above in Example 1 except that the electrolyte described below was used.

A dye-sensitized solar cell having a construction similar to the one described above in Example 1 was produced except that lithium iodide (0.01 g) was added to an electrolytic composition similar to the one described in Example 1.

### Comparative Example 1

An electrolytic composition was obtained by dissolving 0.2 g of polyacrylonitrile, which is a compound that gelates an electrolyte by self-organization, to 10 g of an electrolyte similar to the one described in Example 1.

The electrolytic composition was injected through the injection inlet into an opening of a photoelectric conversion element unit similar to the one described above in Example 1, so as to allow the electrolytic composition to penetrate into the n-type semiconductor electrode and to be injected between the n-type semiconductor electrode and the tin oxide electrode (electroconductive film).

Subsequently, the opening of the photoelectric conversion element unit was sealed with an epoxy resin, followed by leaving the photoelectric conversion element unit at room temperature to produce a photoelectric conversion element, namely, a dye-sensitized solar cell.

### Comparative Example 2

An electrolytic composition was obtained by dissolving 0.2 g of polyvinylpyridine (molecular weight of 60,000) instead of 1,18-octadecyldiimidazole into 10 g of an electrolyte similar to the one described in Example 1.

A dye-sensitized solar cell was produced in a manner similar to the above-described Example 1 except that such an electrolytic composition was used.

### Comparative Example 3

A dye-sensitized solar cell was produced in a similar manner except that 0.01 g of adipic acid was used instead of 0.22 g of 1,2,4,5-tetrakisbromomethylbenzene in Example 1.

With respect to the solar cells of Examples 1 to 13 and Comparative Examples 1 to 3, an energy conversion efficiency was determined when a pseudo solar light was radiated at an intensity of 100 mW/cm². The results are shown in the following Table 1.

Also, the electrolytic compositions used in the solar cells of Examples 1 to 13 and Comparative Examples 1 to 3 were left to stand at 25° C., and the period of time till the viscosity of the electrolytic compositions reached the double of the initial viscosity was measured. The results are shown in the following Table 1 assuming that the period of time till the viscosity of the electrolytic composition of Comparative Example 3 reached the double of the initial viscosity is 1.

TABLE 1

| | Energy | Ratio of time |
|---|---|---|
| | conversion | till the initial |
| | efficiency (%) | viscosity is doubled |
| Example 1 | 7.4 | 20 |
| Example 2 | 7.2 | 20 |
| Example 3 | 7 | 20 |
| Example 4 | 7 | 20 |
| Example 5 | 7 | 20 |
| Example 6 | 6.8 | 20 |
| Example 7 | 7 | 20 |
| Example 8 | 7.6 | 20 |
| Example 9 | 7.7 | 20 |
| Example 10 | 6.7 | 20 |
| Example 11 | 6.3 | 20 |
| Example 12 | 6.2 | 16 |
| Example 13 | 7.1 | 10 |
| Comparative | 5 | 3 |
| Example 1 | | |
| Comparative | 7 | 6 |
| Example 2 | | |
| Comparative | 5 | 1 |
| Example 3 | | |

As will be clear Table 1, the solar cells of Examples 1 to 13 have a higher energy conversion efficiency compared to the solar cells of Comparative Examples 1, 3, and it will be understood that the solar cells of Examples 1 to 13 can reduce the gelation velocity at room temperature as compared with those of Comparative Examples 1 to 3. It can be said that Comparative Example 2 is unsuitable for impregnation as compared with the Examples because of having a high gelation velocity. This is due to the following reason. In Comparative Example 2, an amine compound without having a long-chain alkyl group is used, so that phase separation from the organic halide is less likely to occur, and the gelation reaction is more likely to proceed. The reason why the gelation velocity of Comparative Example 3 is high is that the gelation proceeds by a neutralization reaction between an acidic compound such as adipic acid and a basic compound such as 1,18-octadecyldiimidazole.

In Examples 1 to 13, the rise in the viscosity of the electrolytic composition at room temperature is effectively reduced or restrained, so that the electrolytic composition smoothly penetrates into the cell. This solves the problem of insufficient filling that occurs when a cell has a larger area. Also, the solar cells of Examples 1 to 11 provide with an electrolyte without containing lithium iodide can further reduce the gelation velocity as compared with the solar cells of Examples 12, 13 provide with an electrolyte containing lithium iodide.

Further, the electrolytic compositions used in the solar cells of Examples 1 to 13 and Comparative Examples 1 to 3 were respectively poured into test tubes, and were heated for gelation under a condition (at 60° C. for 30 minutes) similar to that in producing a solar cell, so as to form a gel electrolyte in the test tubes. Each test tube was inclined obliquely at an angle of about 45°. In Examples 1 to 13, the gel electrolyte in the test tubes did not move at all, thereby confirming that Examples 1 to 13 are excellent in the shape retaining property of the gel electrolyte. In contrast, in Comparative Examples 1 to 3, the gel electrolyte in the test tubes inclined obliquely, thereby showing that Comparative Examples 1 to 3 are inferior in the shape retaining property of the gel electrolyte.

In the solar cells of Examples 1 to 13 and Comparative Examples 1 to 3, the cell thickness was reduced to 30 μm, with the result that, while Examples 1 to 13 did not generate poor electric insulation, Comparative Examples 1 to 3 generated poor electric insulation.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A photosensitized solar cell comprising:
an n-type semiconductor electrode containing a dye;
a counter electrode which opposes the n-type semiconductor electrode; and
a gel electrolyte which is provided between the n-type semiconductor electrode and the counter electrode, the gel electrolyte containing a compound and an electrolyte containing iodine, and the compound being produced by reaction of an amine compound having a chain alkyl group with an organic halide having two or more halogen atoms per molecule.

2. The photosensitized solar cell according to claim 1,
wherein the amine compound has a pyridine ring, and the organic halide is a bromomethylbenzene derivative.

3. The photosensitized solar cell according to claim 1,
wherein the amine compound is a nitrogen-containing heterocyclic compound having a chain alkyl group and a pyridine ring.

4. The photosensitized solar cell according to claim 1,
wherein the chain alkyl group has 8 to 30 carbon atoms.

5. The photosensitized solar cell according to claim 1,
wherein the chain alkyl group has 8 to 20 carbon atoms.

6. The photosensitized solar cell according to claim 1, wherein the organic halide has 2 to 1,000,000 halogen atoms per molecule.

7. The photosensitized solar cell according to claim 1,
wherein the electrolyte contains iodine and an iodide of nitrogen-containing heterocyclic compound.

8. An electrolytic composition which is a mixture comprising:
an electrolyte containing iodine;
an amine compound having a chain alkyl group; and
an organic halide having two or more halogen atoms per molecule.

9. The electrolytic composition according to claim 8,
wherein the amine compound has a pyridine ring, and the organic halide is a bromomethylbenzene derivative.

10. The electrolytic composition according to claim 8,
wherein the amine compound is a nitrogen-containing heterocyclic compound having a chain alkyl group and a pyridine ring.

11. The electrolytic composition according to claim 8,
wherein the chain alkyl group has 8 to 30 carbon atoms.

12. The electrolytic composition according to claim 8,
wherein the chain alkyl group has 8 to 20 carbon atoms.

13. The electrolytic composition according to claim 8,
wherein the organic halide has 2 to 1,000,000 halogen atoms per molecule.

14. The electrolytic composition according to claim 8,
wherein the electrolyte contains iodine and an iodide of nitrogen-containing heterocyclic compound.

15. A raw material kit for an electrolytic composition comprising:
a first material containing an amine compound having a chain alkyl group;
a second material containing an organic halide having two or more halogen atoms per molecule; and
a third material containing an electrolyte containing iodine.

16. The raw material kit for an electrolytic composition according to claim 15,
wherein the amine compound has a pyridine ring, and the organic halide is a bromomethylbenzene derivative.

17. The raw material kit for an electrolytic composition according to claim 15,
wherein the chain alkyl group has 8 to 30 carbon atoms.

18. A raw material kit for an electrolytic composition comprising:
a first material which is a mixture containing an amine compound having a chain alkyl group, and a first electrolyte containing iodine; and
a second material which is a mixture containing an organic halide having two or more halogen atoms per molecule, and a second electrolyte containing iodine.

19. The raw material kit for an electrolytic composition according to claim 18,
wherein the amine compound has a pyridine ring, and the organic halide is a bromomethylbenzene derivative.

20. The raw material kit for an electrolytic composition according to claim 18,
wherein the chain alkyl group has 8 to 30 carbon atoms.
